(19) United States
(12) Patent Application Publication
(10) Pub. No.: US 2024/0372319 A1
(43) Pub. Date: Nov. 7, 2024

(54) METHOD OF MANUFACTURING A SEMICONDUCTOR DEVICE AND SEMICONDUCTOR DEVICE

(71) Applicant: ams-OSRAM International GmbH, Regensburg (DE)

(72) Inventors: Laura KREINER, Regensburg (DE); Hubert HALBRITTER, Dietfurt-Toeging (DE); Tansen VARGHESE, Regensburg (DE)

(73) Assignee: ams-OSRAM International GmbH, Regensburg (DE)

(21) Appl. No.: 18/562,624

(22) PCT Filed: Apr. 29, 2022
(86) PCT No.: PCT/EP2022/061595

§ 371 Date: Nov. 20, 2023

(30) Foreign Application Priority Data
May 21, 2021 (DE) 10 2021 113 331.9

(51) Int. Cl. H01S 5/042; H01S 5/183

(52) U.S. Cl. CPC H01S 5/0421; H01S 5/18369

(57) ABSTRACT

A method of manufacturing a semiconductor device includes epitaxially growing a sacrificial layer over a GaN substrate, epitaxially growing a first semiconductor layer over the sacrificial layer and forming a first layer over a first main surface of the first semiconductor layer, the first main surface being on a side of the first semiconductor layer remote from the GaN substrate. The method further includes forming a fluid channel or trench extending through the first layer and the first semiconductor layer to the sacrificial layer, etching the sacrificial layer, including introducing an etchant into the fluid channel or trench, to remove the GaN substrate and forming a second dielectric layer over a second main surface of the first semiconductor layer.

### CROSS-REFERENCE TO RELATED APPLICATIONS

The present application is a national stage entry from International Application No. PCT/EP2022/061595, filed on Apr. 29, 2022, published as International Publication No. WO 2022/243014 A1 on Nov. 24, 2022, and claims priority to German Patent Application No. 10 2021 113 331.9, filed May 21, 2021, the disclosures of all of which are hereby incorporated by reference in their entireties.

### BACKGROUND

A surface-emitting laser device or VCSEL (“Vertical Cavity Surface Emitting Laser”) usually comprises a first and a second resonator mirror and a semiconductor layer stack for generating electromagnetic radiation. The semiconductor layer stack is arranged between the first resonator mirror and the second resonator mirror. Attempts are being made to manufacture a VCSEL in the GaN material system. In particular, attempts are being made to develop a VCSEL in the GaN material system, the VCSEL comprising e.g. dielectric mirrors.

### SUMMARY

It is an object of the present invention to provide an improved method of manufacturing a semiconductor device. Moreover, it is an object of the present invention to provide an improved semiconductor device.

According to embodiments, the above objects are achieved by the claimed matter according to the independent claims. Further developments are defined in the dependent claims.

A method of manufacturing a semiconductor device comprises epitaxially growing a sacrificial layer over a GaN substrate, epitaxially growing a first semiconductor layer over the sacrificial layer and forming a first layer over a first main surface of the first semiconductor layer, the first main surface being on a side of the first semiconductor layer remote from the GaN substrate. The method further comprises forming a fluid channel extending through the first layer and the first semiconductor layer to the sacrificial layer, etching the sacrificial layer, comprising introducing an etchant into the fluid channel, to remove the GaN substrate, and forming a second dielectric layer over the second main surface of the first semiconductor layer.

For example, forming a fluid channel may comprise forming an opening in the first layer, the opening having a larger extension in a vertical direction than in a horizontal direction.

The method may further comprise forming a passivation layer over a sidewall of the fluid channel, the passivation layer being resistant to the etchant.

According to embodiments, the method may further comprise forming a carrier substrate over the first layer before forming the fluid channel, the fluid channel extending through the carrier substrate.

According to further embodiments, forming a fluid channel may comprise forming a trench in the first layer and in the first semiconductor layer, the trench extending in a first horizontal direction.

The method may further comprise forming a further trench in the first layer and in the first semiconductor layer, the further trench extending in a second horizontal direction.

For example, a passivation layer may be formed over a sidewall of the trench, the passivation layer being resistant to the etchant.

The method may further comprise forming a carrier substrate over the first layer after forming the fluid channel.

The method may further comprise epitaxially forming further semiconductor layers to form a semiconductor layer stack before forming the first layer.

For example, forming the further semiconductor layers may comprise forming an etch stopping layer. The method may further comprise an etching step after removing the GaN substrate. For example, a final point of this etching step may be detected or determined using the etch stopping layer.

For example, the etch stopping layer may be formed after forming the sacrificial layer. According to further embodiments, the etch stopping layer may be formed before forming the sacrificial layer. According to further embodiments, a first etch stopping layer (or intermediate layer) may be formed before forming the sacrificial layer. A further etch stopping layer may be formed after forming the sacrificial layer.

According to embodiments, the first layer may comprise a first dielectric layer. For example, the method may comprise forming further dielectric layers to form a first dielectric layer stack comprising the first dielectric layer, and to form a second dielectric layer stack comprising the second dielectric layer.

According to further embodiments, the first layer may comprise a further semiconductor layer. For example, the method may comprise forming further semiconductor layers to form a first resonator mirror comprising the further semiconductor layers.

According to embodiments, etching the sacrificial layer may further comprise applying a voltage to a workpiece comprising the sacrificial layer.

According to embodiments, a semiconductor device comprises a first semiconductor layer comprising GaN, a first dielectric layer over a first main surface of the first semiconductor layer, and a second dielectric layer over a second main surface of the first semiconductor layer.

For example, the first semiconductor layer may be part of a semiconductor layer stack comprising the first semiconductor layer of a first conductivity type, a second semiconductor layer of a second conductivity type, and an active zone between the first semiconductor layer and the second semiconductor layer.

The first dielectric layer may be part of a first dielectric layer stack, and the second dielectric layer may be part of a second dielectric layer stack. The semiconductor device may be a vertical cavity surface emitting laser and the first dielectric layer stack may form a first resonator mirror and the second dielectric layer stack may form a second resonator mirror.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1J illustrate cross-sectional views of a workpiece when performing a method of manufacturing a semiconductor device according to embodiments.

FIG. 2A shows a top view of a wafer after forming fluid channels.

FIG. 2B shows a cross-sectional view of a semiconductor device according to embodiments.

FIGS. 3A to 3I illustrate cross-sectional views of a workpiece when performing a method of manufacturing a semiconductor device according to further embodiments.

FIG. 4A shows a top view of a wafer including fluid channels.

FIG. 4B shows a cross-sectional view of a semiconductor device according to further embodiments.

FIG. 4C summarizes a method according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to further embodiments, the growth substrate may be an insulating substrate such as a sapphire substrate. Depending on the purpose of use, the semiconductor may be based on a direct or an indirect semiconductor material. Examples of semiconductor materials particularly suitable for generation of electromagnetic radiation comprise nitride-compound semiconductors, by which e.g. ultraviolet or blue light or longer wavelength light may be generated, such as GaN, InGaN, AIN, AlGaN, AlGaInN, phosphide-compound semiconductors, by which e.g. green or longer wavelength light may be generated such as GaAsP, AlGaInP, GaP, AlGaP, as well as further semiconductor materials including AlGaAs, SiC, ZnSe, GaAs, ZnO, Ga₂O₃, diamond, hexagonal BN und combinations of these materials. Further examples of semiconductor materials may as well be silicon, silicon-germanium and germanium. The stoichiometric ratio of the compound semiconductor materials may vary.

In the context of the present specification, the material for forming components of the semiconductor device specifically comprises nitride-compound semiconductors.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the surface of a wafer or a die.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

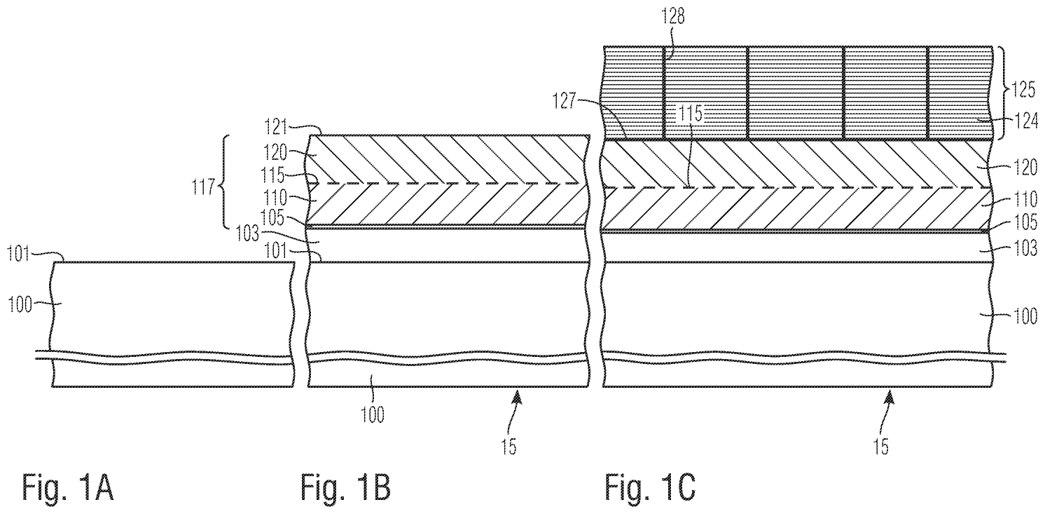

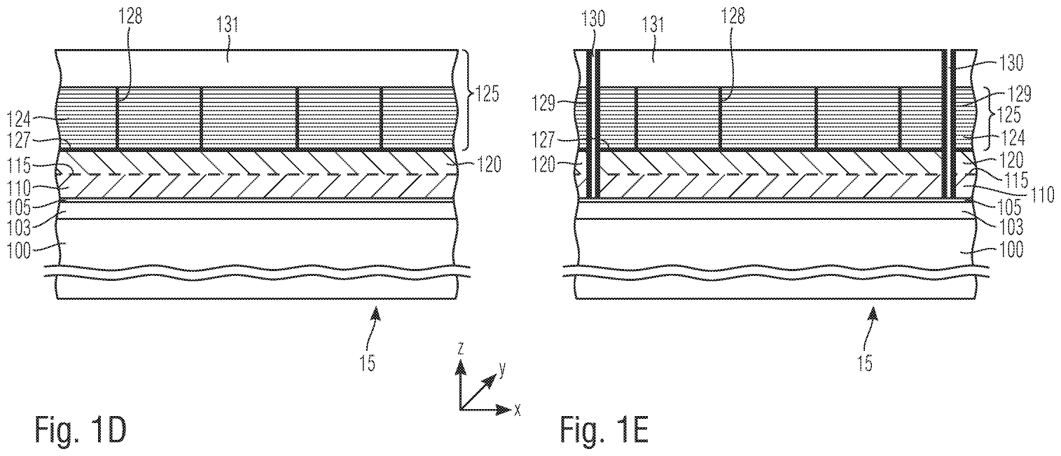

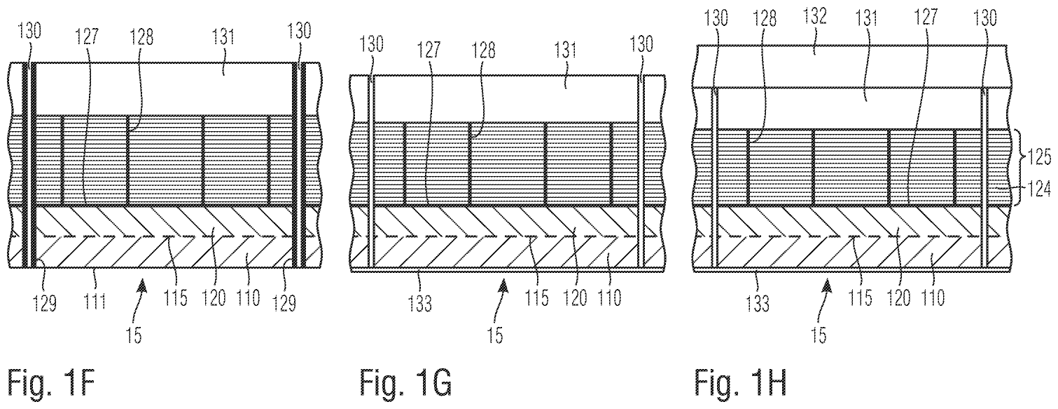

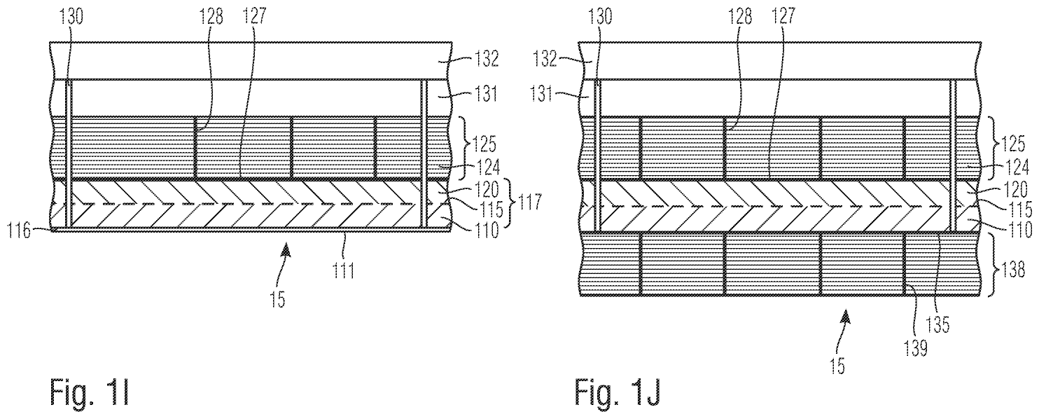

Starting point for performing a method according to embodiments is a GaN substrate 100 having a first main surface 101 as is shown in FIG. 1A, for example. A semiconductor layer stack 117 is formed over the first main surface 101 of the semiconductor substrate 100. The semiconductor layer stack comprises a sacrificial layer 105 which, for example, may be n-doped GaN, e.g. GaN doped with silicon or germanium at a doping level higher than around 7E18 cm⁻³. For example, the sacrificial layer 105 may be formed in direct contact with the first main surface 101 of the GaN substrate 100. According to further embodiments, an intermediate layer 103 may be arranged between the sacrificial layer 105 and the GaN substrate 100. The intermediate layer 103 may be of a composition different from the composition of the sacrificial layer 105. Examples of the composition of the intermediate layer comprise AlGaN with a higher Al content, or with a lower doping level, or undoped, so that the electrochemical etch that will be described later with respect to FIGS. 1E and 1F stops at this layer. The intermediate layer 103 may also be removed later by selectively etching or by another selective removal method such as CMP. The intermediate layer 103 may protect the GaN substrate from the etching. As a result, after removing the GaN substrate from the workpiece, the GaN substrate may be easier re-used, for example. Thereafter, a second semiconductor layer 110 is epitaxially grown over the GaN substrate 100. For example, the second semiconductor layer 110 may comprise GaN. The second semiconductor layer 110 may be doped with dopants of a second conductivity type, e.g. n type. Thereafter, an active zone 115 may be formed.

The active zone 115 may be configured to generate electromagnetic radiation. The active zone 115 may, for example, comprise a pn junction, a double heterostructure, a single quantum well (SQW) or a multi quantum well (MQW) for generating radiation. The wording “quantum well” does not further specify the dimension of the quantization. Accordingly, the term “quantum well” comprises quantum wells, quantum wires and quantum dots as well as any combination of these layers.

Thereafter, a first semiconductor layer 120 of a second conductivity type, e.g. p-type may be formed over the active zone 115. FIG. 1B shows an example of a resulting workpiece 15. FIG. 1B also shows a first main surface 121 of the first semiconductor layer 120. The first semiconductor layer 120 may form the topmost layer of the semiconductor layer stack 117.

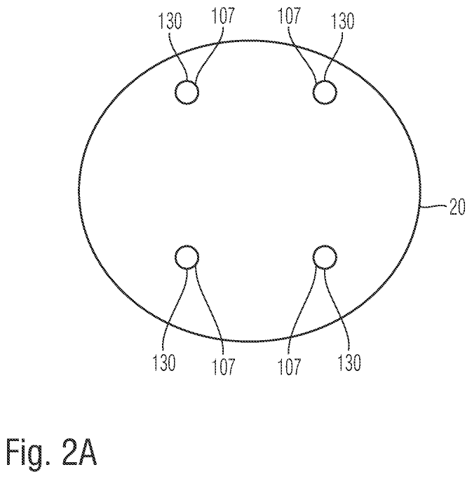

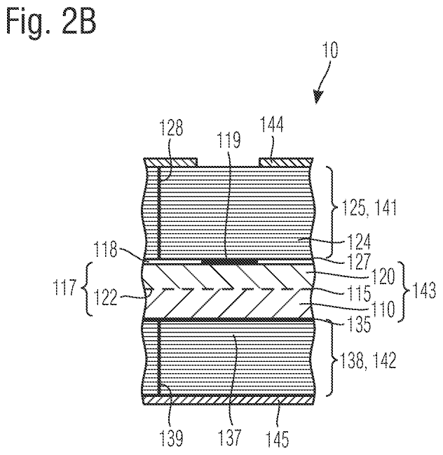

A dielectric layer 118 (not shown in FIG. 1B, shown in FIG. 2B) may be then deposited over the first semiconductor layer 120 and may be patterned to form holes to define current injection apertures 119.

Thereafter, a contact layer 127, e.g. comprising a transparent conductive material such as a transparent conductive oxide e.g. ITO (Indium Tin Oxide) may be formed over the semiconductor layer stack. The contact layer 127 may be adjacent to the first main surface 121 of the first semiconductor layer 120. Thereafter, a first layer, e.g. a first dielectric layer 124, may be formed over the contact layer 127. The first dielectric layer 124 may be part of a first dielectric layer stack 125. For example, the first dielectric layer stack 125 may comprise dielectric layers forming a Bragg mirror.

According to further embodiments, the first layer may be a further semiconductor layer that is epitaxially grown. In this case, the Bragg mirror may comprise a semiconductor layer stack. According to these embodiments, the contact layer 127 and the dielectric layer 118 including apertures 119 may be dispensed with.

Generally, a Bragg mirror may comprise first layers of a first composition and second layers of a second composition which are alternately stacked. The first and the second layers may be dielectric layers or, alternatively, semiconductor layers. For example, the first layers may have a high refractive index and the second layers may have a low refractive index. In this context, the terms “high refractive index” and “low refractive index” may mean that the high refractive index is larger than a certain value that may depend from the material system. The low refractive index is smaller than the certain value.

For example, the layer thickness may be λ/4 or a multiple of λ/4, wherein λ denotes the wavelength of the light to be reflected in the specific medium. The Bragg mirror may comprise more than two different layers. For example, a maximum number of layers may be 50. A typical layer thickness of the single layers may be 30 to 90 nm, e.g. approximately 50 nm. The layer stack may further comprise one or more layers having a thickness larger than approximately 180 nm, e.g. larger than 200 nm.

Contact structures 128 for contacting the contact layer 127 may be formed in the first dielectric layer stack 125. For example, forming the contact structures 128 may comprise forming via openings that vertically extend to the contact layer 127. The via openings may be filled with a conductive material. According to further embodiments, a contact to the contact layer 127 or the first semiconductor layer may be provided in alternative ways. For example, the dielectric layer stack 125 may be etched in an edge region of the workpiece. Further, a conductive layer, for example a metal, may be formed over the contact layer 127 or the first semiconductor layer 120 in the edge region. According to embodiments in which the first resonator mirror comprises semiconductor layers, the contact to the first semiconductor layer may be accomplished via contact elements that are arranged on top of the first resonator mirror. These contact elements may also be provided at a later processing stage.

FIG. 1C shows an example of a resulting workpiece 15. A plurality of contact structures 128 vertically extend through the first dielectric layer stack 125 to the contact layer 127. Thereafter, a carrier substrate 131 may be attached to a surface of the first dielectric layer stack 125. For example, this may be accomplished by bonding a silicon wafer to the first dielectric layer stack 125, optionally followed by thinning the silicon wafer.

FIG. 1D shows an example of a resulting workpiece 15.

In a next step, fluid channels 130 are formed in the resulting workpiece 15. In particular, the fluid channels 130 are formed to extent from a surface of the carrier substrate 131 to the sacrificial layer 105. Forming a fluid channel may comprise forming an opening in the first dielectric layer. The opening may have a larger extension in a vertical direction, e.g. z-direction then in a horizontal direction, e.g. x- or y-direction. For example, the method for forming the opening may comprise a DRIE (“Deep Reactive Ion Etching”) for etching the carrier substrate. The method may further comprise a reactive ion etching process combined with an ICP (“Inductively Coupled Plasma”) etching process for etching the first dielectric layer stack 125 and the semiconductor layer stack. For example, the fluid channel 130 may have a lateral extension of some μm.

According to a further modification, openings may be already defined in the carrier substrate 131 before attaching the carrier substrate 131 to the workpiece 15.

The sidewalls of the openings may be coated with an etch resistant material forming a passivation layer 129. A material of the passivation layer 129 may, for example, comprise silicon oxide or silicon nitride. For example, this may be accomplished using an ALD (“Atomic Layer Deposition”) process in order to cover the sidewalls even in openings having high aspect ratios. Thereafter, an anisotropic etching process may be performed in order to remove the coating material from horizontal portions.

FIG. 1E shows an example of a resulting workpiece 15. As is shown in FIG. 1E, the fluid channels 130 extend to the sacrificial layer 105. As a result, an etchant may be introduced so as to reach the sacrificial layer 105.

In the next step, an etching process is performed. Etching may be performed using an etchant such as HNO3 while a voltage is applied to the sacrificial layer 105. Depending on the applied voltage and the doping level of the sacrificial layer 105, the sacrificial layer 105 may be completely etched. As a result, the substrate 100 is removed from the workpiece 15.

FIG. 1F shows an example of a resulting workpiece 15. As is shown, the substrate 100 and, optionally, the intermediate layer 103 are removed from the workpiece 15. As a result, a first main surface 111 of the second semiconductor layer 110 now is not covered.

In order to protect the exposed first main surface 111 of the second semiconductor layer 110, a protective layer 133 may be formed. For example, the protective layer 133 may be a protective foil that may be laminated over the first main surface 111 of the second semiconductor layer. The protective foil may be a release foil or a temporary carrier that may be easily removed from the workpiece 15.

FIG. 1G shows an example of a resulting workpiece 15. For further processing, a second carrier 132, e.g. a silicon wafer may be formed over the carrier substrate 131. The second carrier may close the fluid channels 130.

FIG. 1H shows an example of a resulting workpiece. Thereafter, further processing steps may be performed. For example, the protective layer 133 may be removed from the first main surface 111 of the second semiconductor layer.

FIG. 1I shows an example of a resulting workpiece 15. As is shown in FIG. 1I, the semiconductor layer stack 117 may further comprise an etch stopping layer 116. Due to the etch stopping layer, a height of the semiconductor layer 117 and, hence, a length of an optical resonator may be precisely defined using a further etching process. For example, due to the presence of the etch stopping layer 116, a final point of an etching process may be exactly determined. According to further embodiments, instead of an etch stopping layer a CMP (“chemical mechanical polishing”) stop layer may be used and the height of the semiconductor layer stack 117 may be set using a CMP method.

Further components of a semiconductor device may be formed. For example, a second contact layer 135 comprising a transparent conductive material, e.g. a transparent conductive oxide may be formed over the first main surface 111 of the second semiconductor layer 110. A second resonator mirror may be formed over the second contact layer 135. For example, the second resonator mirror may comprise a second dielectric layer stack 138. Further, second via contacts 139 may be formed in the second dielectric layer stack 138.

FIG. 1J shows an example of a resulting workpiece.

As has been described, the process provides a method for manufacturing a GaN based semiconductor layer stack comprising e.g. dielectric layers on either side of the semiconductor layer stack. The GaN based semiconductor layers may be epitaxially grown over a GaN growth substrate. Due to the special manufacturing process which comprises removing the GaN growth substrate after forming a first dielectric layer 124, it is possible to form dielectric layers on either side of the GaN based semiconductor layer stack. For example, the dielectric layers may be formed by sputtering. For example, the dielectric layers may have large differences of their refractive indices. Hence, it is possible to form resonator mirrors having a high reflectivity. As a result, a GaN based VCSEL may be manufactured. According to further embodiments, the first layer may be a further semiconductor layer. Moreover, at least one of the resonator mirrors may comprise one or more semiconductor layers.

After removing the GaN substrate 100, it is possible to recycle the GaN substrate 100. Hence, resources may be saved. The method described may be used for manufacturing arbitrary semiconductor devices.

FIG. 2A shows a top view of a wafer 20 comprising fluid channels 130, wherein the fluid channels 130 comprise openings 107 that extend to the sacrificial layer, as has been explained with reference to FIGS. 1A to 1J. As is shown, a lateral extension of the fluid channels 130 is small compared to the vertical extension of the fluid channels. For example, the fluid channels may have a diameter of 1 to 50 μm. More specifically, a diameter may be 5 to 20 μm, for example, 8 to 12 μm. The diameter need not be circular but may have an arbitrary shape. The fluid channels 130 may be distributed over the wafer so that the working time is independent from the wafer size. The fluid channels may have a distance of about some cm, e.g. 2.2 cm.

FIG. 2B shows an example of a semiconductor device 10 according to embodiments. The semiconductor device 10 shown in FIG. 2D comprises a first semiconductor layer 120 comprising GaN and a first dielectric layer 124 over a first main surface 121 of the first semiconductor layer 120. The semiconductor device 10 further comprises a second dielectric layer 137 over a second main surface 122 of the first semiconductor layer 120. In FIG. 2B, the first semiconductor layer 120 is part of a semiconductor layer stack comprising the first semiconductor layer 120 of a first conductivity type, a second semiconductor layer 110 of a second conductivity type, and an active zone 115 between the first semiconductor layer 120 and the second semiconductor layer 110. For example, the semiconductor layers of the semiconductor layer stack 117 may comprise GaN. The first dielectric layer 124 may be part of a first dielectric layer stack 125 and the second dielectric layer 137 may be part of a second dielectric layer stack 138. The first dielectric layer stack 125 may form a first resonator mirror 141 and the second dielectric layer stack 138 may form a second resonator mirror 142. The first semiconductor layer 120 may be electrically contacted via the contact layer 127 and the via contact 128 to a first contact element 144. A dielectric layer 118 may be arranged between the first semiconductor layer 120 and the contact layer 127. The dielectric layer 118 is patterned to form holes to define current injection apertures 119.

A second contact element 145 may be electrically connected to the second semiconductor layer 110 via the second via contact 139 and the second contact layer 135. The first dielectric layer 124 may cover the entire first main surface 121 surface of the first semiconductor layer 120. The second dielectric layer 137 may cover the entire second main surface 122 of the first semiconductor layer 120. A growth substrate may be absent from the semiconductor device 10.

For example, a layer thickness of the first semiconductor layer may be less than 1 μm or even less than 500 nm.

Although a semiconductor device according to embodiments has been explained while referring to a VCSEL, it is clearly to be understood that a semiconductor device according to embodiments may as well be implemented as a different optoelectronic or other device. Generally, a semiconductor device according to embodiments may comprise arbitrary semiconductor components formed in a GaN layer comprising dielectric layers over either sides of the GaN layer.

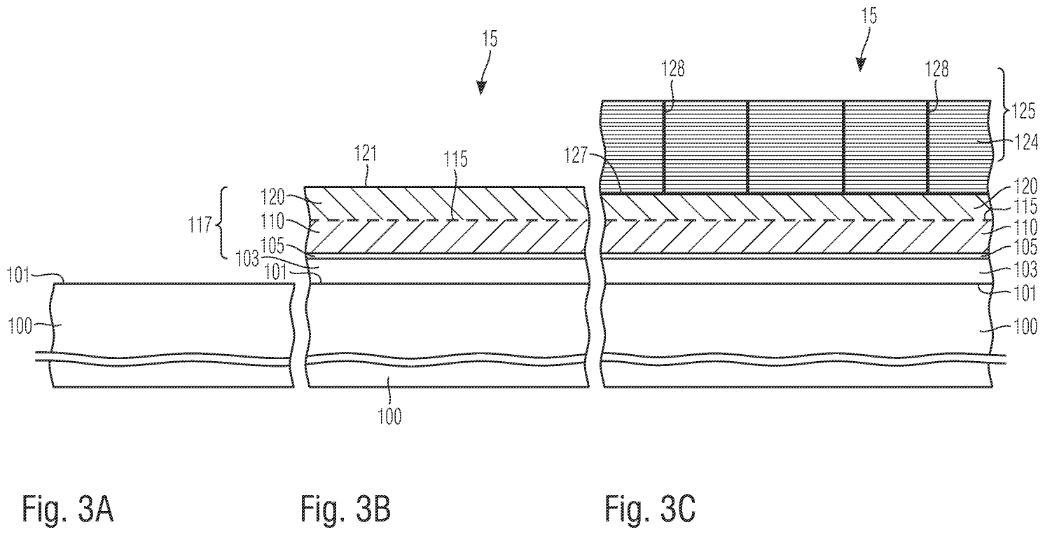

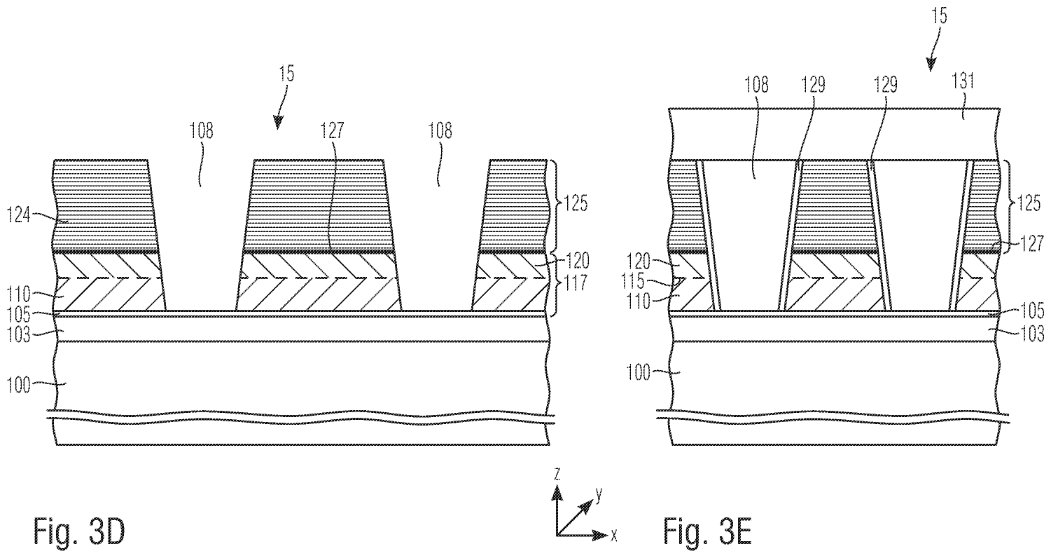

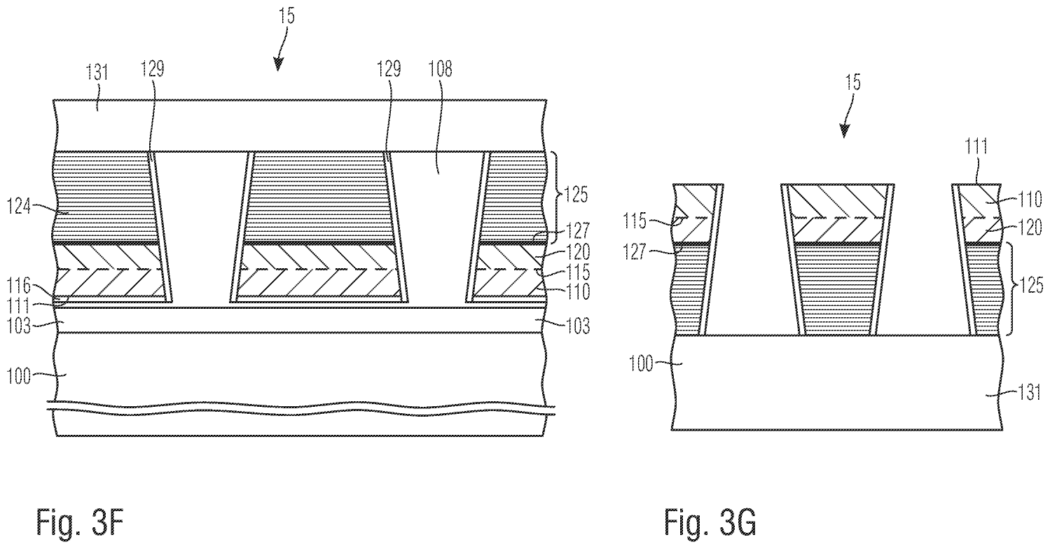

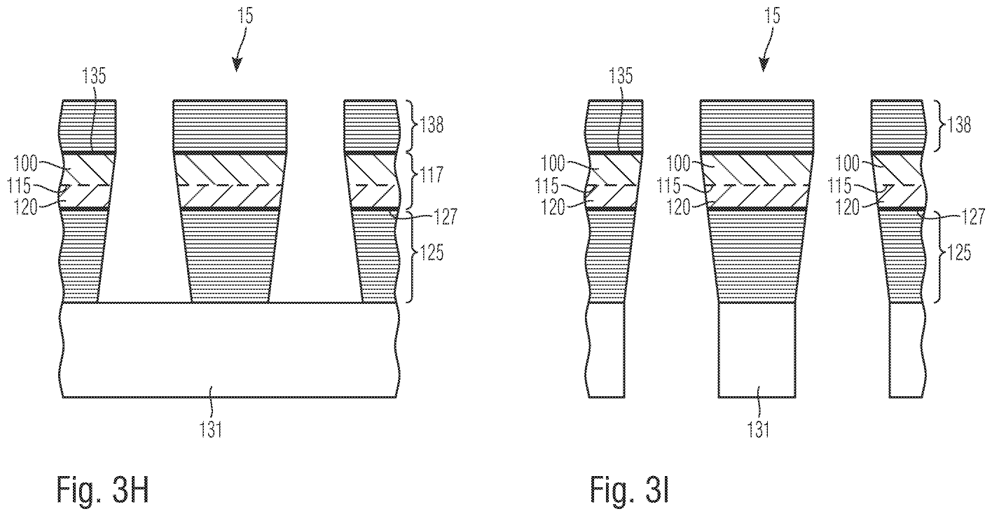

According to further embodiments, instead of openings having small horizontal extensions, the fluid channel may be implemented by trenches extending in a first or a second horizontal direction. A corresponding method will be explained in the following with reference to FIGS. 3A to 3I.

In a similar manner as has been explained above, a starting point for performing the method according to embodiments may be a GaN substrate 100 having a first main surface 101 as illustrated in FIG. 3A.

Thereafter, as is shown in FIG. 3B, a semiconductor layer stack 117 may be epitaxially grown over the first main surface 101 of the GaN substrate 100. In a similar manner as has been discussed above with reference to FIG. 1B, the semiconductor layer stack 117 may comprise a sacrificial layer 105 that may, for example, be an n doped GaN layer, e.g. doped with silicon or germanium at a doping level higher than around 7E18 cm⁻³. Thereafter, a second semiconductor layer 110 of a second conductivity type, e.g. n-type, an active zone 115 and a first semiconductor layer 120 of a first conductivity type, e.g. p-type may be epitaxially grown over the sacrificial layer 105. A first main surface 121 of the first semiconductor layer 120 is not covered.

Optionally, an intermediate layer 103 may be epitaxially formed between the GaN substrate 100 and the sacrificial layer 105. The intermediate layer 103 may be of a composition different from the composition of the sacrificial layer 105. Examples of the composition of the intermediate layer comprise AlGaN with a higher Al content, or with a lower doping level, or undoped, so that the electrochemical etch that will be described later with respect to FIGS. 3E and 3F stops at this layer. The intermediate layer 103 may also be removed later by selectively etching or by another selective removal method such as CMP. The intermediate layer 103 may protect the GaN substrate from the etching. As a result, after removing the GaN substrate from the workpiece, the GaN substrate may be easier re-used, for example.

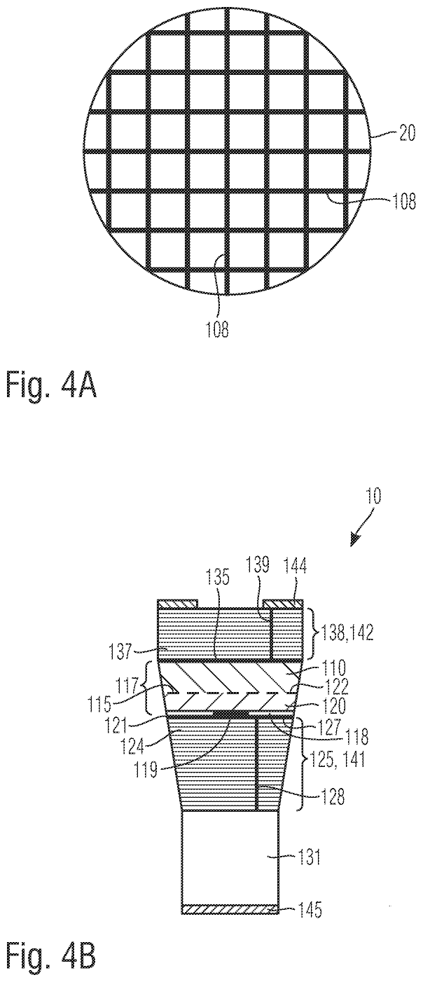

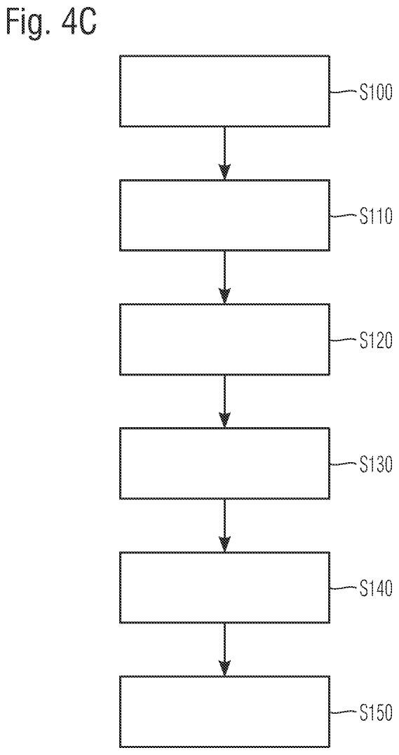

A dielectric layer 118 (not shown in FIG. 3B) may be then deposited over the first semiconductor layer 120 and may be patterned to form holes to define current injection apertures 119 (not shown in FIG. 3B, shown in FIG. 4B).

As is shown in FIG. 3C, thereafter, the transparent conductive layer 127 may be formed over the first semiconductor layer 120. Then, a first layer, e.g. a first dielectric layer 124 is formed over the transparent conductive layer 127. Further dielectric layers may be formed over the first dielectric layer 124 to form a first dielectric layer stack 125 which implements a Bragg mirror. FIG. 3C shows an example of a resulting structure.

According to further embodiments, the first layer may be a further semiconductor layer that is epitaxially grown. In this case, the Bragg mirror may comprise a semiconductor layer stack. According to these embodiments, the contact layer 127 and the dielectric layer 118 including apertures 119 may be dispensed with.

Further, via contacts 128 extending to the contact layer 127 are formed and are filled with an electrically conductive material. According to further embodiments, a contact to the contact layer 127 or the first semiconductor layer may be provided in alternative ways. For example, the dielectric layer stack 125 may be etched in an edge region of the workpiece. Further, a conductive layer, for example a metal, may be formed over the contact layer 127 or the first semiconductor layer 120. According to embodiments, in which the resonator mirror comprises semiconductor layers, the contact elements may be formed on top of the semiconductor layers forming the first resonator mirror.

As is shown in FIG. 3D, trenches 108 are etched in the layer stack comprising the first dielectric layer stack 125 and part of the semiconductor layer stack 117. The trenches 108 are etched to extend to the sacrificial layer 105. For example, the trenches 108 may be etched using a dry etching process. Due to etching the trenches, the semiconductor layer stack is patterned to mesas. For example, the wafer may be diced to single chips along the trenches 108 at a later processing stage.

FIG. 3D shows an example of a resulting structure. For example, the trenches 108 may have a width of less than 2 μm, e.g. 1 to 2 μm. The width may be measured in the x direction.

For example, a sidewall passivation layer 129 may be formed. For example, a material that is etch resistant may be formed on the sidewalls of the trenches 108. Materials of the sidewall passivation layer 129 comprise dielectric layers such as silicon oxide or silicon nitride. For example, the sidewall passivation layer 129 may comprise a passivation layer stack. Further, an anisotropic etching process may be performed so as to remove the passivation layer 129 from horizontal portions of the trench 108.

Thereafter, a carrier substrate 131 is attached to the exposed surface of the first dielectric layer stack 125. For example, the carrier substrate may comprise a semiconductor material such as germanium or silicon. Optionally, the carrier substrate 131 may be thinned after attaching the carrier substrate 131 to the workpiece 15. FIG. 3E shows an example of a resulting structure.

For example, the carrier may be bonded via ITO-ITO bonding, dielectric-dielectric-bonding or metal-metal bonding. Thereafter, an etchant, e.g. HNO₃ may be introduced into the trenches 108. Moreover, a voltage may be applied to the workpiece comprising the sacrificial layer 105. Depending on the applied voltage and the doping level of the sacrificial layer 105, the sacrificial layer 105 may be completely etched. As a result, the GaN substrate is removed from the workpiece 15.

FIG. 3F shows an example of a workpiece after removal the sacrificial layer 105. According to embodiments, the semiconductor layer stack 117 may comprise a specific etch stopping layer 116 which may be used for exactly designing a thickness of a layer stack when performing a further etching process.

The etch stopping layer 116 can have a composition that is different from the composition of the sacrificial layer. Materials of the etch stopping layer 116 may comprise AlGaN with a higher Al content, or with a lower doping level, or undoped, so that the electrochemical etch stops at this layer. The etch stopping layer 116 may also be removed later by selectively etching or another selective material removal such as CMP and stopping on another etch stop layer below. Due to this etch stopping layer, it is possible to exactly define the length of an optical resonator of a VCSEL. When exactly setting the resonator length, it is possible to adjust the thickness of the layer stack so that an antinode is present a position of the active zone 115 and a node is present at the interface between the semiconductor layer stack 117 and an adjacent layer. As a result, absorption of generated electromagnetic radiation may be reduced, and generation of electromagnetic radiation may be increased. In summary, the efficiency of the semiconductor device may be further improved. For example, due to the presence of the etch stopping layer 116, a final point of an etching process may be exactly determined. According to further embodiments, instead of an etch stopping layer a CMP (“chemical mechanical polishing”) stop layer may be used and the height of the semiconductor layer stack 117 may be set using a CMP method.

FIG. 3G shows an example of a workpiece 15 after removing the GaN substrate 100 and after flipping the workpiece 15.

Thereafter, a second dielectric layer 137 may be formed over the semiconductor layer stack 117. Moreover, further layers of a second dielectric layer stack 138 may be formed over the semiconductor layer stack 117. For example, the dielectric layers may be formed by sputtering. Thereafter, further processing steps may be performed in order to form further layers of over the workpiece. For example, metal layers may be deposited and patterning processes may be performed. FIG. 3H shows an example of a resulting workpiece 15.

Thereafter, as is shown in FIG. 31, the wafer may be singulated into single semiconductor chips taking the trenches 108 as a position where to separate the single chips.

FIG. 4A shows a top view of a wafer 20 comprising trenches 108. As is illustrated, the trenches 108 may extend in the x-direction and in the y-direction to form a crisscross pattern.

FIG. 4B shows a cross-sectional view of a semiconductor device that may implement a VCSEL. The semiconductor device 10 shown in FIG. 4B comprises a first semiconductor layer 120, a first dielectric layer 124 over a first main surface 121 of the first semiconductor layer 120 and a second dielectric layer 137 over a second main surface 122 of the first semiconductor layer 120. The first semiconductor layer 120 may be part of a semiconductor layer stack 117 comprising the first semiconductor layer 120 of a first conductivity type, a second semiconductor layer 110 of a second conductivity type, and an active zone 115 between the first semiconductor layer 120 and the second semiconductor layer 110. The first dielectric layer 124 may be part of a first dielectric layer stack 125. The second dielectric layer 137 may be part of a second dielectric layer stack 138. For example, the semiconductor device may be a vertical cavity surface emitting laser and the first dielectric layer stack 125 implements a first resonator mirror 141. The second dielectric layer stack 138 implements a second resonator mirror 142. The first semiconductor layer 120 may be electrically connected to a first contact element 145 via the first contact layer 127, the first via contact 128 and the conductive carrier substrate 131. A dielectric layer 118 may be arranged between the first semiconductor layer 120 and the contact layer 127. The dielectric layer 118 is patterned to form holes to define current injection apertures 119.

The second semiconductor layer 110 may be electrically connected to the second contact element 144 via the second contact layer 135 and a second via contact 139.

The first dielectric layer 124 may cover the entire first main surface 121 of the first semiconductor layer 120. The second dielectric layer 137 may cover the entire second main surface 122 of the first semiconductor layer 120. A growth substrate may be absent from the semiconductor device 10. For example, a layer thickness of the first semiconductor layer may be less than 1 μm or even less than 500 nm.

Although embodiments described herein specifically refer to a vertical cavity surface emitting laser, it is apparent to the person skilled in the art, that the methods described may be likewise employed in order to manufacture different semiconductor devices comprising GaN. For example, the methods may be also employed for manufacturing different optoelectronic semiconductor devices such as LEDs, edge emitting lasers or PCSELS (“photonic crystal surface emitting laser”). Furthermore, the methods may be used for manufacturing further semiconductor devices e.g. transistors, e.g. HEMTs (“high electron mobility transistor”) or others. Hence, the semiconductor devices described herein may be implemented in an arbitrary manner including optoelectronic semiconductor devices such as LEDs, edge emitting lasers or PCSELs and further devices such as transistors, e.g. HEMTs and others.

As has been described, the GaN growth substrate 100 is removed from the workpiece. As a result, a recycling of the GaN substrate is possible, leading to reduced cost.

FIG. 4C summarizes a method according to embodiments. A method of manufacturing a semiconductor device comprises epitaxially growing (S100) a sacrificial layer over a GaN substrate, epitaxially growing (S110) a first semiconductor layer over the sacrificial layer, and forming (S120) a first layer over a first main surface of the first semiconductor layer, the first main surface being on a side of the first semiconductor layer remote from the GaN substrate. The method further comprises forming (S130) a fluid channel extending through the first layer and the first semiconductor layer to the sacrificial layer, etching (S140) the sacrificial layer, comprising introducing an etchant into the fluid channel, to remove the GaN substrate, and forming (S150) a second dielectric layer over the second main surface of the first semiconductor layer.

As has been described, the GaN growth substrate 100 is removed from the workpiece. As a result, a recycling of the GaN substrate is possible, leading to reduced cost and a resource efficient method. Due to the fact that the etchant is introduced in the fluid channel, it is possible to etch the sacrificial layer from a position inside the workpiece. Compared with a case in which the etchant etches from the edge of the workpiece, the etching process may be accelerated. The method may be applied to the manufacture of arbitrary semiconductor devices.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1-16. (canceled)

17. A semiconductor device comprising:
a first semiconductor layer comprising GaN,
a first dielectric layer over a first main surface of the first semiconductor layer, and
a second dielectric layer over a second main surface of the first semiconductor layer.

18. The semiconductor device according to claim 17, further comprising a first contact element that is arranged on a side of the first dielectric layer remote from the first semiconductor layer, the first contact element being electrically connected to the first semiconductor layer via a first via contact extending through the first dielectric layer.

19. The semiconductor device according to claim 17, wherein a distance between the first dielectric layer and the second dielectric layer is less than 1 μm.

20. The semiconductor device according to claim 17, wherein the first semiconductor layer is part of a semiconductor layer stack comprising the first semiconductor layer of a first conductivity type, a second semiconductor layer of a second conductivity type, and an active zone between the first semiconductor layer and the second semiconductor layer.

21. The semiconductor device according to claim 17, wherein
the first dielectric layer is part of a first dielectric layer stack, and
the second dielectric layer is part of a second dielectric layer stack,
wherein the semiconductor device is a vertical cavity surface emitting laser and the first dielectric layer stack forms a first resonator mirror (141) and the second dielectric layer stack forms a second resonator mirror.

22. A method of manufacturing a semiconductor device, comprising:
epitaxially growing a sacrificial layer over a GaN substrate;
epitaxially growing a first semiconductor layer over the sacrificial layer;
forming a first layer over a first main surface of the first semiconductor layer, the first main surface being on a side of the first semiconductor layer remote from the GaN substrate;
forming a fluid channel extending through the first layer and the first semiconductor layer to the sacrificial layer, comprising forming a trench in the first layer and in the first semiconductor layer, the trench extending in a first horizontal direction;
etching the sacrificial layer, comprising introducing an etchant into the fluid channel, to remove the GaN substrate; and
forming a second dielectric layer over a second main surface of the first semiconductor layer.

23. The method of claim 22, wherein forming the fluid channel comprises forming an opening in the first layer, the opening having a larger extension in a vertical direction than in a horizontal direction.

24. The method of claim 22, further comprising:
forming a passivation layer over a sidewall of the fluid channel, the passivation layer being resistant to the etchant.

25. The method of claim 22, further comprising forming a carrier substrate over the first layer before forming the fluid channel, the fluid channel extending through the carrier substrate.

26. The method of claim 22, further comprising:
forming a further trench in the first layer and in the first semiconductor layer, the second trench extending in a second horizontal direction.

27. The method of claim 22 further comprising:
forming a passivation layer over a sidewall of the trench, the passivation layer being resistant to the etchant.

28. The method of claim 22, further comprising:
attaching a carrier substrate over the first layer after forming the fluid channel.

29. The method claim 22, further comprising:
epitaxially forming further semiconductor layers to form a semiconductor layer stack before forming the first layer.

30. The method according to claim 29, wherein forming the further semiconductor layers comprises forming an etch stopping layer after epitaxially growing the sacrificial layer and the method further comprises an etching step after removing the GaN substrate.

31. The method of claim 22, further comprising:
forming a further etch stopping layer before epitaxially growing the sacrificial layer.

32. The method of claim 22, wherein the first layer comprises a first dielectric layer.

33. The method of claim 32, further comprising:
forming further dielectric layers to form a first dielectric layer stack comprising the first dielectric layer, and to form a second dielectric layer stack comprising the second dielectric layer.

34. The method of claim 22, wherein the first layer comprises a further semiconductor layer.

35. The method according to claim 34, further comprising:
forming further semiconductor layers to form a first resonator mirror comprising the further semiconductor layers.

36. The method of claim 22, wherein etching the sacrificial layer further comprises applying a voltage to a workpiece comprising the sacrificial layer.
